(19) United States
(12) Patent Application Publication
(10) Pub. No.: US 2016/0374221 A1
(43) Pub. Date: Dec. 22, 2016

(54) VACUUM ATTACHMENT DEVICE AND METHOD FOR ATTACHING DISPLAY MOTHERBOARD

(71) Applicants: BOE TECHNOLOGY GROUP CO., LTD., Beijing (CN); ORDOS YUANSHENG OPTOELECTRONICS CO., LTD., Ordos (CN)

(72) Inventors: Jun HOU, Beijing (CN); Tao ZHANG, Beijing (CN); Liang LIU, Beijing (CN)

(21) Appl. No.: 15/159,226

(22) Filed: May 19, 2016

(30) Foreign Application Priority Data
Jun. 18, 2015 (CN) 201510342308.9

(51) Int. Cl. H05K 7/14; H05K 1/14

(52) U.S. Cl. CPC H05K 7/1417; H05K 1/14

(57) ABSTRACT

Disclosed are a vacuum attachment device and a method for attaching display motherboard. The inventive vacuum attachment device comprises: a first bearing platform and a second bearing platform; a curing unit provided along the inner peripheral. area of one of the first bearing platform and the second bearing platform and configured to cure the sealant; and a control unit configured to control operations of the curing unit. The vacuum attachment device further comprises a heating unit, provided along the inner peripheral area of the other one of the first bearing platform and the second bearing platform and configured to heat the sealant under the control of the control unit. Therefore, the first and second motherboard can be more firmly attached. Also, it is possible to eliminate or reduce the mismatching and ungluing of the first and second motherboard during transportation, thereby improving the quality of the display motherboard.

### CROSS-REFERENCE TO RELATED APPLICATION

This application claims the priority of Chinese Patent Application No. 20151034.2308.9 filed on Jun. 18, 2015, titled “Vacuum attachment device and method for attaching display motherboard” in the Chinese Intellectual Property Office, the disclosure of which is incorporated herein by reference.

### FIELD OF THE INVENTION

The invention relates to the field of technologies of display panel attachment process, and in particular to a vacuum attachment device and a method for attaching display motherboard.

### BACKGROUND OF THE INVENTION

Generally, a display device includes a first substrate and a second substrate which are attached to each other, wherein the first substrate and the second substrate are attached by using a vacuum attachment device.

The attachment process in the prior art includes:

placing a first motherboard including a plurality of first substrates on a machine platform of a attachment device; applying UV adhesive (ultraviolet curable adhesive) to an inner peripheral area of a second motherboard which will be attached to the first motherboard, and applying glass filler to a peripheral packaging area of each of the first substrates of the first motherboard; at this point, supplying vacuum to the environment of the attachment device, and attaching the first motherboard and the second motherboard to form a display motherboard; after the attachment, introducing nitrogen (or air) into the vacuum environment of the attachment device; placing the attached first motherboard and second motherboard in atmospheric environment; under such a circumstance, irradiating the inner peripheral area of the first motherboard with a UV lamp (ultraviolet lamp), such that the UV adhesive thereon is cured; and then irradiating the position of the glass filler with laser, to realize the attachment of each of display panels. In accordance to the packaging area, the display motherboard is cut into a plurality of display panels.

The inventor has found following disadvantages in the prior art: due to the characteristic of the UV adhesive, only approximately 50% of the UV adhesives are cured by the chemical reaction during the irradiation of the UV lamp. Therefore, the UV adhesive has relatively weak adhesive strength and would be completely cured only by a thermo-curing process. However, the attached first motherboard and second motherboard is inclined to be mismatched and unglued due to insufficient curing strength when it is transported during the thermo-curing process, resulting in the deterioration of the accurately attached first motherboard and second motherboard. Thus it is possible to affect the quality of final product.

### SUMMARY OF THE INVENTION

As for the above problems residing in the vacuum attachment device in the prior art, the embodiments of the disclosure provide a vacuum attachment device and a method for attaching display motherboard to increase the adhesive force between the first motherboard and the second motherboard,

As a first aspect of the disclosure, there is provided a vacuum attachment device, comprising: a first bearing platform and a second bearing platform, which are arranged oppositely and configured to bear a first motherboard and a second motherboard, respectively, wherein a sealant is applied to an inner peripheral area of the first motherboard or the second motherboard; a curing unit, which is provided along the inner peripheral area of one of the first bearing platform and the second bearing platform and configured to cure the sealant; and a control unit, which is configured to control operations of the curing unit. The vacuum attachment device further comprises a heating unit, which is provided along the inner peripheral area of the other one of the first bearing platform and the second bearing platform and configured to heat the sealant under the control of the control unit.

Preferably, the sealant is a UV curable adhesive, and the curing unit is a UV lamp.

Preferably, the vacuum attachment device further comprises a sensing unit, the sensing unit is arranged on the inner peripheral area of the other one of the first bearing platform and the second bearing platform and positioned oppositely to the curing unit, and when the sensing unit detects the ultraviolet light emitted from the UV lamp, the control unit controls the heating unit to heat the UV curable adhesive.

Preferably, the heating unit is an infrared lamp.

Preferably, the vacuum attachment device further comprises a drive unit, which is configured to drive the first bearing platform and the second bearing platform to move relatively, such that the first motherboard conies into contact with the second motherboard.

Preferably, the sealant is a thermosetting adhesive.

Preferably, the control unit is configured to control operations of the curing unit, such that the curing unit is disabled.

As a second aspect of the disclosure, there is provided a method for attaching display motherboards using the vacuum attachment device as described above, the method comprising steps of:

Step S11, applying UV curable adhesive to the inner peripheral area of the first motherboard or the second motherboard;

Step S12, aligning the first bearing platform carrying the first motherboard with the second bearing platform carrying the second motherboard;

Step S13, driving the first bearing platform to move towards the second bearing platform, such that the first motherboard and the second motherboard are attached; and

Step S14, controlling the UV lamp to emit ultraviolet light and irradiate the area where the UV curable adhesive is applied, and controlling the heating unit to heat the UV curable adhesive.

Preferably, Step S14 further comprises: after the sensing unit detects the ultraviolet light, controlling the heating unit to heat the UV curable adhesive.

As a third aspect of the disclosure, there is provided a method for attaching display motherboards using the vacuum attachment device as described above, the method comprising steps of:

Step S21, applying thermosetting adhesive to the inner peripheral area of the first motherboard or the second motherboard;

Step S22, aligning the first bearing platform carrying the first motherboard with the second bearing platform carrying the second motherboard;

Step S23, driving the first bearing platform to move towards the second bearing platform, such that the first motherboard and the second motherboard are attached; and

Step S24, controlling to activate the heating unit to heat the thermosetting adhesive while controlling the curing unit to be disabled.

The embodiments of the disclosure have following advantageous effects:

Compared with the vacuum attachment device in the prior art, the vacuum attachment device according to the disclosure has not only a curing unit but also a heating unit. Therefore, in the embodiments of the disclosure, such a manner in which UV curing and heat curing are combined may be employed, such that the first motherboard and the second motherboard can be more firmly attached. Also, it is possible to eliminate or reduce the mismatching and ungluing of the first motherboard and the second motherboard during transportation, thereby improving the quality of the display motherboard.

### BRIEF DESCRIPTION OF THE DRAWINGS

FIG. 1 is a cross-section view schematically illustrating a vacuum attachment device according to the disclosure.

### DETAILED DESCRIPTION OF THE EMBODIMENTS

In order to better understand the technical solutions of the disclosure by those skilled in the art, the disclosure will be further described in detail in conjunction with the accompanying drawings and specific embodiments.

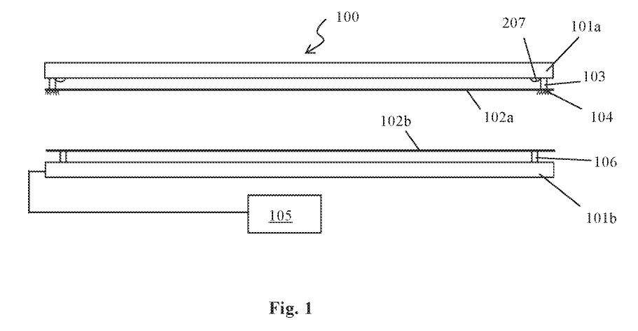

As shown in FIG. 1, a vacuum attachment device 100 may includes: a first bearing platform 101a and a second bearing platform 101b, which are arranged oppositely and configured to bear a first motherboard 102a and a second motherboard 102b, respectively, wherein a sealant 104 is applied to an inner peripheral area of the first motherboard 102a or the second motherboard 102b; a curing unit 106, which is provided along the inner peripheral area of one of the first bearing platform 101a and second bearing platform 101b and configured to cure the sealant 104; and a control unit (PLC device) 105, which is configured to control operations of the curing unit 106. In addition, the vacuum attachment device 100 may further include a heating unit 103, which is provided along the inner peripheral area of the other one of the first bearing platform 101a and second bearing platform 101b and configured to heat the sealant 104 under the control of the control unit 105.

Herein, the sealant could be an ultraviolet curable adhesive (UV adhesive) or a thermosetting adhesive. Of course, any other sealant can be used as long as the first motherboard 102a and the second motherboard 102b can be attached to each other. When the UV curable adhesive is employed as the sealant, the ultraviolet lamp (UV lamp) is used as the curing unit accordingly. In the following first optional embodiment, the UV curable adhesive is used as the sealant, while the UV lamp is used as the curing unit. In the second optional embodiment, the thermosetting adhesive is used as the sealant. In the description of the embodiments of the disclosure, the curing unit 106 is arranged on the second bearing platform 101b, and the heating unit 103 is arranged on the first bearing platform 101a. Of course, it should be understood that the curing unit 106 may be arranged on the first bearing platform 101a, and the heating unit 103 may be arranged on the second bearing platform 101b.

### First Optional Embodiment

In this embodiment, a vacuum attachment device 100 may include: a first bearing platform 101a and a second bearing platform 101b, which are arranged oppositely and configured to bear a first motherboard 102a and a second motherboard 102b, respectively, wherein a sealant (for example, a UV curable adhesive) 104 is applied to an inner peripheral area of the first motherboard 102a; a curing unit (for example, a UV lamp) 106, which is provided along an inner peripheral area of the second bearing platform 101b and configured to cure the sealant 104; a control unit (PLC device) 105, which is configured to control operations of the curing unit 106; and a heating unit 103, which is provided along the inner peripheral area of the first bearing platform 101a and configured to heat the sealant 104 under the control of the control unit 105. In addition, as shown in FIG. 1, the vacuum attachment device 100 may further include a sensing unit (for example, UV sensor) 207 which is arranged on the first bearing platform 101a and positioned oppositely to the curing unit 106.

In particular, after the first motherboard 102a on the first bearing platform 101a and the second motherboard 102b on the second bearing platform 101b are attached to each other, the UV lamp may irradiate the area of the motherboard where the UV curable adhesive is applied with ultraviolet light, so as to cure the UV adhesive. In the meanwhile, the sensing unit 207 may detect the ultraviolet light. At this time, the control unit 105 may control to activate the heating unit 103 to heat the UV adhesive. In other words, during the attachment of the first motherboard and the second motherboard, the UV curing by the curing unit 106 and the heat curing by the heating unit 103 are performed simultaneously. In such a manner, the UV curable adhesive can be sufficiently cured, so as to more firmly laminate the first motherboard 102a and the second motherboard 102b. Also, it is possible to eliminate or at least reduce the mismatching and ungluing of the first motherboard and the second motherboard during transportation, thereby improving the quality of the display motherboard.

In this embodiment, the curing unit 106 (i.e., UV lamp) is arranged on the inner peripheral area of the second bearing platform 101b. Preferably, the sensing unit 207 is arranged on the inner peripheral area of the first bearing platform 101a and positioned oppositely to the UV lamp.

When the control unit 105 controls the UV lamp to emit ultraviolet light, since the sensing unit 207 is arranged right above the UV lamp, the sensing unit 207 is able to immediately detect the ultraviolet light emitted from the UV lamp. Then, the control unit 105 controls the heating unit 103 to heat the UV curable adhesive between the first motherboard 102a and the second motherboard 102b. Therefore, it is possible to more firmly laminate the first motherboard 102a and the second motherboard 102b.

Preferably, in this embodiment, the heating unit 103 could be an infrared (IR) lamp. The infrared lamp may have advantages of simple structure and energy saving. Of course, other heating units, such as electric heating resistance wire, may also be employed.

Preferably, in this embodiment, the vacuum attachment device 100 may further include: a drive unit (not shown), which is configured to drive the first bearing platform 101a and the second bearing platform 101b to move relatively, such that the first motherboard 102a comes into contact with the second motherboard 102b. Usually, the drive unit may control the first bearing platform 101a to move towards the second bearing platform 101b.

In addition, the disclosure also provides a method for attaching display motherboards using the vacuum attachment device as described above. The method may particularly include steps of:

Step S11, applying a sealant (a UV curable adhesive in this embodiment) to the inner peripheral area of the first motherboard 102a or the second motherboard 102b (the first motherboard 102a in this embodiment);

Step S12, aligning the first bearing platform 101a carrying the first motherboard 102a with the second bearing platform 101b carrying the second motherboard 102b;

Step S13, driving the first bearing platform 101a to move towards the second bearing platform 101b, such that the first motherboard 102a and the second motherboard 102b are attached; and

Step S14, controlling the curing unit 106 (a UV lamp in this embodiment) to emit ultraviolet light and irradiate an area where the sealant 104 (the UV curable adhesive in this embodiment) is applied, and in the meanwhile, after the sensing unit 207 detects the ultraviolet light, controlling the heating unit 103 to heat and sufficiently cure the UV curable adhesive.

In the method for attaching display motherboard according to this embodiment, due to the combination of UV curing and heat curing, the first motherboard and the second motherboard can be more firmly attached. Also, it is possible to eliminate or reduce the mismatching and ungluing of the first motherboard and the second motherboard during transportation, thereby improving the quality of the display motherboard.

### Second Optional Embodiment

In this embodiment, a vacuum attachment device 100 may include: a first bearing platform 101a and a second bearing platform 101b, which are arranged oppositely and configured to bear a first motherboard 102a and a second motherboard 102b, respectively, wherein a sealant (for example, a thermosetting adhesive) 104 is applied to an inner peripheral area of the first motherboard 102a; a curing unit (for example, a UV lamp) 106, which is provided along an inner peripheral area of the second bearing platform 101b; a control unit (PLC device) 105, which is configured to control operations of the curing unit 106, such that the curing unit 106 is disabled; and a heating unit 103, which is provided along the inner peripheral area of the first bearing platform 101a and configured to heat the sealant 104 under the control of the control unit 105.

Since the thermosetting adhesive is used as the sealant in this embodiment, the attachment of the first motherboard and the second motherboard can be realized only by heating the thermosetting adhesive by the heating unit.

Preferably, in this embodiment, the heating unit 103 could be an infrared (IR) lamp. The infrared lamp may have advantages of simple structure and energy saving. Of course, other heating units, such as electric heating resistance wire, may also be employed.

Preferably, in this embodiment, the vacuum attachment device 100 may further include: a drive unit (not shown), which is configured to drive the first bearing platform 101a and the second bearing platform 101b to move relatively, such that the first motherboard 102a comes into contact with the second motherboard 102b. Usually, the drive unit may control the first bearing platform 101a to move towards the second bearing platform 101b.

In addition, the disclosure also provides a method for attaching display motherboards using the vacuum attachment device as described above. The method may particularly include steps of:

Step S21, applying a sealant (a thermosetting adhesive in this embodiment) to the inner peripheral area of the first motherboard 102a or the second motherboard 102b (the first motherboard 102a in this embodiment);

Step S22, aligning the first bearing platform 101a carrying the first motherboard 102a with the second bearing platform 101b carrying the second motherboard 102b;

Step S23, driving the first bearing platform 101a to move towards the second bearing platform 101b, such that the first motherboard 102a and the second motherboard 102b are attached; and

Step S24, controlling to activate the heating unit 103 to heat the thermosetting adhesive while controlling the curing unit 106 to be disabled.

In the method for attaching display motherboard according to this embodiment, it is possible to apply the thermosetting adhesive to the first motherboard or the second motherboard and cure the thermosetting adhesive only by using the heating unit. Therefore, the first motherboard and the second motherboard can also be more firmly attached. Also, it is possible to eliminate or reduce the mismatching and ungluing of the first motherboard and the second motherboard during transportation, thereby improving the quality of the display motherboard.

It should be understood that the above embodiments are merely exemplary embodiments for the purpose of illustrating the principle of the invention, and the invention is not limited thereto, Various modifications and improvements can be made by a person having ordinary skill in the art without departing from the spirit and the essence of the invention. Accordingly, all of the modifications and improvements also fall into the protection scope of the invention.

1. A vacuum attachment device, comprising:
a first bearing platform and a second bearing platform, which are arranged oppositely and configured to bear a first motherboard and a second motherboard, respectively, wherein a sealant is applied to an inner peripheral area of the first motherboard or the second motherboard;
a curing unit, which is provided along the inner peripheral area of one of the first bearing platform and the second bearing platform and configured to cure the sealant; and
a control unit, which is configured to control operations of the curing unit,
wherein, the vacuum attachment device further comprises a heating unit, which is provided along the inner peripheral area of the other one of the first bearing platform and the second bearing platform and configured to heat the sealant under the control of the control unit.

2. The vacuum attachment device according to claim 1, wherein
the sealant is a UV curable adhesive, and the curing unit is a UV lamp.

3. The vacuum attachment device according to claim 2, wherein
the vacuum attachment device further comprises a sensing unit,
the sensing unit is arranged on the inner peripheral area of the other one of the first bearing platform and the second bearing platform and positioned oppositely to the curing unit,
when the sensing unit detects the ultraviolet light emitted from the UV lamp, the control unit controls the heating unit to heat the UV curable adhesive.

4. The vacuum attachment device according to claim 3, wherein
the heating unit is an infrared lamp.

5. The vacuum attachment device according to claim 1, wherein
the vacuum attachment device further comprises a drive unit, which is configured to drive the first bearing platform and the second bearing platform to move relatively, such that the first motherboard comes into contact with the second motherboard.

6. The vacuum attachment device according to claim 3, wherein
the vacuum attachment device further comprises a drive unit, which is configured to drive the first bearing platform and the second bearing platform to move relatively, such that the first motherboard comes into contact with the second motherboard.

7. The vacuum attachment device according to claim 1, wherein
the sealant is a thermosetting adhesive.

8. The vacuum attachment device according to claim 7, wherein
the control unit is configured to control operations of the curing unit, such that the curing unit is disabled.

9. The vacuum attachment device according to claim 8, wherein
the heating unit is an infrared lamp.

10. The vacuum attachment device according to claim 8, wherein
the vacuum attachment device further comprises a drive unit, which is configured to drive the first bearing platform and the second bearing platform to move relatively, such that the first motherboard comes into contact with the second motherboard.

11. A method for attaching display motherboards using the vacuum attachment device according to claim 2, the method comprising steps of:
Step S11, applying UV curable adhesive to the inner peripheral area of the first motherboard or the second motherboard;
Step S12, aligning the first bearing platform carrying the first motherboard with the second bearing platform carrying the second motherboard;
Step S13, driving the first bearing platform to move towards the second bearing platform, such that the first motherboard and the second motherboard are attached; and
Step S14, controlling the UV lamp to emit ultraviolet light and irradiate an area where the UV curable adhesive is applied, and controlling the heating unit to heat the UV curable adhesive.

12. The method according to claim 11, wherein
the vacuum attachment device further comprises a sensing unit, which is arranged on the inner peripheral area of the other one of the first bearing platform and the second bearing platform and positioned oppositely to the curing unit.

13. The method according to claim 12, Step S14 further comprises:
after the sensing unit detects the ultraviolet light, controlling the heating unit to heat the UV curable adhesive.

14. The method according to claim 13, wherein
the heating unit is an infrared lamp.

15. The method according to claim 11, wherein
the vacuum attachment device further comprises a drive unit, which is configured to drive the first bearing platform and the second bearing platform to move relatively, such that the first motherboard comes into contact with the second motherboard.

16. The method according to claim 12, wherein
the vacuum attachment device further comprises a drive unit, which is configured to drive the first bearing platform and the second bearing platform to move relatively, such that the first motherboard comes into contact with the second motherboard.

17. The method according to claim 13, wherein
the vacuum attachment device further comprises a drive unit, which is configured to drive the first bearing platform and the second bearing platform to move relatively, such that the first motherboard comes into contact with the second motherboard.

18. A method for attaching display motherboards using the vacuum attachment device according to claim 7, the method comprising steps of:
Step S21, applying thermosetting adhesive to the inner peripheral area of the first motherboard or the second motherboard;
Step S22, aligning the first bearing platform carrying the first motherboard with the second bearing platform carrying the second motherboard;
Step S23, driving the first bearing platform to move towards the second bearing platform, such that the first motherboard and the second motherboard are attached; and
Step S24, controlling to activate the heating unit to heat the thermosetting adhesive while controlling the curing unit to be disabled.

19. The method according to claim 18, wherein
the heating unit is an infrared lamp.

20. The method according to claim 18, wherein
the vacuum attachment device further comprises a drive unit, which is configured to drive the first bearing platform and the second bearing platform to move relatively, such that the first motherboard comes into contact with the second motherboard.
